(19) United States
(12) Patent Application Publication
(10) Pub. No.: US 2020/0144474 A1
(43) Pub. Date: May 7, 2020

(54) CONDUCTIVE FILM, THERMOELECTRIC CONVERSION LAYER, THERMOELECTRIC CONVERSION ELEMENT, THERMOELECTRIC CONVERSION MODULE, METHOD FOR MANUFACTURING CONDUCTIVE FILM, AND COMPOSITION

(71) Applicant: FUJIFILM Corporation, Tokyo (JP)

(72) Inventors: Hiroki SUGIURA, Ashigara-kami-gun (JP); Naoyuki HAYASHI, Ashigara-kami-gun (JP); Toyohisa OYA, Ashigara-kami-gun (JP)

(73) Assignee: FUJIFILM Corporation, Tokyo (JP)

(21) Appl. No.: 16/733,879

(22) Filed: Jan. 3, 2020

Related U.S. Application Data
(63) Continuation of application No. PCT/JP2018/025194, filed on Jul. 3, 2018.

(30) Foreign Application Priority Data
Jul. 6, 2017 (JP) 2017-132627

(51) Int. Cl. H01L 35/26; H01L 35/34

(52) U.S. Cl. CPC H01L 35/26; H01L 35/34

(57) ABSTRACT

A first object of the present invention is to provide a conductive film having excellent substrate adhesiveness and a method for manufacturing the conductive film. A second object of the present invention is to provide a thermoelectric conversion layer, a thermoelectric conversion element, and a thermoelectric conversion module which are formed using the conductive film. A third object of the present invention is to provide a composition for forming the conductive film.

The conductive film according to an embodiment of the present invention contains carbon nanotubes and an insulating polymer having a polar group, in which a content of oxygen atoms in the carbon nanotubes is 0.5 to 5.0 atm %, and a content of the insulating polymer with respect to the carbon nanotubes is 10% to 100% by mass.

### CROSS-REFERENCE TO RELATED APPLICATIONS

This application is a Continuation of PCT International Application No. PCT/JP2018/025194 filed on Jul. 3, 2018, which claims priority under 35 U.S.C. § 119(a) to Japanese Patent Application No. 2017-132627 filed on Jul. 6, 2017. The above application is hereby expressly incorporated by reference, in its entirety, into the present application.

### BACKGROUND OF THE INVENTION

### 1. Field of the Invention

The present invention relates to a conductive film, a thermoelectric conversion layer, a thermoelectric conversion element, a thermoelectric conversion module, a method for manufacturing a conductive film, and a composition.

### 2. Description of the Related Art

Carbon materials represented by carbon nanotubes (hereinafter, referred to as “CNT” as well) exhibit excellent electric conductivity. Therefore, it is acknowledged that these materials can be used for various purposes. For example, Example 4 in JP2014-239092A discloses a method for forming a thermoelectric conversion layer by using a composition which contains a dispersion liquid containing CNT and carboxymethyl cellulose as a binder.

### SUMMARY OF THE INVENTION

The inventors of the present invention prepared a dispersion composition with reference to Example 4 in JP2014-239092A and tried to form a film (conductive film) containing carbon nanotubes and carboxymethyl cellulose on various substrates.

As a result, it has been revealed that the obtained film is poor in substrate adhesiveness. Particularly, it has been revealed that the adhesiveness of the film to a non-polar substrate needs to be further improved.

An object of the present invention is to provide a conductive film excellent in substrate adhesiveness and a method for manufacturing the conductive film.

Another object of the present invention is to provide a thermoelectric conversion layer, a thermoelectric conversion element, and a thermoelectric conversion module which are formed using the conductive film.

Still another object of the present invention is to provide a composition for forming the conductive film.

In order to achieve the above objects, the inventors of the present invention conducted intensive examinations. As a result, the inventors have found that the above objects can be achieved using carbon nanotubes in which the content of oxygen atoms is adjusted to fall into a predetermined range by a modification treatment. Based on the finding, the inventors have accomplished the present invention.

That is, the inventors have found that the above objects can be achieved by the following constitution.

[1] A conductive film containing carbon nanotubes and an insulating polymer having a polar group, in which a content of oxygen atoms in the carbon nanotubes is 0.5 to 5.0 atm %, and a content of the insulating polymer with respect to a content of the carbon nanotubes is 10% to 100% by mass.

[2] The conductive film described in [1], in which the carbon nanotubes are single-layer carbon nanotubes.

[3] The conductive film described in [1] or [2], in which a G/D ratio of the carbon nanotubes is equal to or higher than 30.

[4] The conductive film described in any one of [1] to [3], in which the insulating polymer is a water-soluble polymer.

[5] The conductive film described in [4], in which the water-soluble polymer is polysaccharides.

[6] The conductive film described in [5], in which the polysaccharides are cellulose or derivatives thereof.

[7] A thermoelectric conversion layer including the conductive film described in any one of [1] to [6].

[8] A thermoelectric conversion element comprising the thermoelectric conversion layer described in [7].

[9] A thermoelectric conversion module comprising a plurality of the thermoelectric conversion elements described in [8].

[10] A method for manufacturing the conductive film described in any one of [1] to [6], including a step of performing a modification treatment on carbon nanotubes such that a content of oxygen atoms becomes 0.5 to 5.0 atm %, a step of obtaining a composition which contains the carbon nanotubes, in which the content of oxygen atoms is adjusted by the modification treatment, and an insulating polymer having a polar group and in which a content of the insulating polymer with respect to a content of the carbon nanotubes is 10% to 100% by mass, and a step of forming a conductive film on a substrate by using the composition.

[11] A composition containing carbon nanotubes, in which a content of oxygen atoms is 0.5 to 5.0 atm %, and an insulating polymer having a polar group, in which a content of the insulating polymer with respect to a content of the carbon nanotubes is 10% to 100% by mass.

According to the present invention, it is possible to provide a conductive film excellent in substrate adhesiveness and a method for manufacturing the conductive film.

Furthermore, according to the present invention, it is possible to provide a thermoelectric conversion layer, a thermoelectric conversion element, and a thermoelectric conversion module which are formed using the conductive film.

In addition, according to the present invention, it is possible to provide a composition for forming the conductive film.

### BRIEF DESCRIPTION OF THE DRAWINGS

FIG. 1 is a cross-sectional view showing an example of an embodiment of a thermoelectric conversion element of the present invention.

FIG. 2 is a scanning electron microscope (SEM) image of a conductive film according to an embodiment of the present invention.

FIG. 3 is a SEM image of a conductive film of Comparative Example 1.

FIG. 4 is a schematic view of a thermoelectric conversion module prepared in Examples.

FIG. 5 is a schematic view showing a device for measuring output of the thermoelectric conversion module.

### DESCRIPTION OF THE PREFERRED EMBODIMENTS

Hereinafter, the present invention will be specifically described.

The following constituents will be described based on typical embodiments of the present invention in some cases, but the present invention is not limited to the embodiments.

In the present specification, a range of numerical values described using “to” means a range which includes the numerical values listed before and after “to” as a lower limit and an upper limit.

In the present specification, the description of “(meth)acryl” means “either or both of acryl and methacryl”.

[Conductive Film]

One of the characteristics of the conductive film according to an embodiment of the present invention is that the conductive film contains carbon nanotubes (hereinafter, referred to as “specific CNT” as well), in which a content of oxygen atoms is 0.5 to 5.0 atm %, and an insulating polymer (hereinafter, referred to as “specific insulating polymer” as well) having a polar group at a specific quantitative ratio.

Due to the constitution described above, the conductive film according to the embodiment of the present invention exhibits excellent adhesiveness with respect to both the polar and non-polar substrates and exhibits excellent electric conductivity.

The mechanism working for the conductive film to exhibit the above characteristics is unclear but is assumed to be as below by the inventors of the present invention.

Presumably, in a case where a conductive film is formed on a substrate by using a composition containing the specific CNT and the specific insulating polymer at a predetermined quantitative ratio, in the conductive film, by the oxygen atoms (specifically, oxygenic functional groups) present in the specific CNT molecules, the specific CNT may interact with the polar group in the specific insulating polymer through hydrogen bonding and the like, and consequently, the specific insulating polymer may coat the periphery of the specific CNT. Herein, “coat” includes an aspect in which the specific insulating polymer coats a portion of the specific CNT and an aspect in which the specific insulating polymer coats the entirety of the specific CNT. Particularly, the content of oxygen atoms in the specific CNT is adjusted to be 0.5 to 5.0 atm %. Presumably, for this reason, the specific CNT may excellently interact with the specific insulating polymer, the specific insulating polymer may wet and spread on the surface of the specific CNT, and consequently, a film of the specific insulating polymer formed on the periphery of the specific CNT may be relatively thin.

The inventors of the present invention have found that in a case where the specific CNT and the specific insulating polymer, which are assumed to interact with each other in the conductive film, are caused to have a predetermined relationship in terms of the amount thereof used, the adhesiveness of the conductive film with respect to various substrates is improved. Specifically, the inventors have found that in a case where the content of the specific insulating polymer with respect to the content of the specific CNT is 10% to 100% by mass, the conductive film expresses excellent adhesiveness with respect to both the polar substrate and non-polar substrate.

In a case where the content of the specific insulating polymer with respect to the content of the specific CNT is less than 10% by mass, the conductive film does not exhibit excellent adhesiveness with respect to a polar substrate. Generally, CNT is known to exhibit hydrophobicity. Although the specific CNT is made slightly hydrophilic by setting the content of oxygen atoms to be 0.5 to 5 atm %, in a case where the content of the specific insulating polymer is less than 10% by mass, the specific CNT is excessively exposed, and accordingly, the conductive film does not exhibit excellent adhesiveness with respect to a polar substrate. Furthermore, in a case where the content of the specific insulating polymer is less than 10% by mass, it is difficult for the conductive film to exhibit excellent adhesiveness with respect to a non-polar substrate. This is because the specific insulating polymer acts as a binder as well. In a case where the content of the specific insulating polymer with respect to the specific CNT is less than 10% by mass, the film becomes brittle. Therefore, in a case where the conductive film is immersed in a solvent, voids occur between CNT and the substrate, the solvents enter the voids, and the conductive film is easily peeled off.

In a case where the content of the specific insulating polymer with respect to the content of the specific CNT is greater than 100% by mass, the conductive film exhibits excellent adhesiveness with respect to a polar substrate but does not exhibit excellent adhesiveness with respect to a non-polar substrate. Furthermore, it has been confirmed that in a case where the content of the specific insulating polymer with respect to the content of the specific CNT is greater than 100% by mass, the electric conductivity is reduced.

Presumably, the conductive film according to the embodiment of the present invention may be thinner than the film of the specific insulating polymer as described above. It is considered that accordingly, even though the conductive film contains the specific insulating polymer, the tunnel effects may not be suppressed, carriers could pass through the specific insulating polymer, and consequently, excellent electric conductivity could be maintained.

The inventors of the present invention have also found that in a case where the conductive film is applied to a thermoelectric conversion layer, the thermoelectric conversion layer exhibits high electric conductivity and low thermal conductivity, and consequently, a figure of merit Z becomes excellent.

The closer the CNT to each other in the thermoelectric conversion layer (in other words, the shorter the distance between a plurality of CNT), the higher the thermal conductivity of the thermoelectric conversion layer, and consequently, the figure of merit Z is reduced. In contrast, presumably, in the conductive film according to the embodiment of the present invention, the periphery of the specific CNT may be covered with the film of the specific insulating polymer as described above. It is considered that accordingly, phonons may be easily scattered within the interface between the specific CNT and the film of the specific insulating polymer, and as a result, low thermal conductivity may be exhibited. It has been confirmed that in a case where the content of the specific insulating polymer with respect to the content of the specific CNT is less than 10% by mass, thermal conductivity is improved.

Hereinafter, the components contained in the conductive film according to the embodiment of the present invention will be described first, and then the method for manufacturing the conductive film according to the embodiment of the present invention will be described.

<Specific CNT>

The specific CNT is not particularly limited as long as the content of oxygen atoms is within a predetermined range.

Hereinafter, the content of oxygen atoms will be described first, and then the method for manufacturing the specific CNT will be described.

### (Content of Oxygen Atoms)

In the present invention, the content of oxygen atoms in the specific CNT is measured by the following method by using X-ray Photoelectron Spectroscopy (XPS).

<<Measurement by X-Ray Photoelectron Spectroscopy (XPS)>>

By XPS, “peak area A of oxygen atoms (is) derived from C—O or C═O at about 531 eV” and “peak area B of carbon atoms (is) at about 285 eV” are determined. Based on the obtained peak areas, atomic percent is calculated by the following Equation (1).

Content of oxygen atoms (atm %)=(A)/(A+B)×100 Equation (1):

In Equation (1), A represents a peak area of oxygen atoms (is) derived from C—O or C═O at about 531 Ev, and B represents a peak area of carbon atoms (is) at about 285 eV.

The content of oxygen atoms in the specific CNT is 0.5 to 5.0 atm %. In view of further improving the effects of the present invention, the content of oxygen atoms in the specific CNT is preferably 1.0 to 3.0 atm %.

As will be described in the section of raw material CNT which will be described later, the specific CNT may be single-layer CNT, double-layer CNT, multilayered CNT, and the like. In a case where the conductive film is used as a conductive material, the specific CNT may be any of single-layer CNT, double-layer CNT, or multilayered CNT. In a case where the conductive film is used for the purpose such as a thermoelectric conversion layer that needs to have the characteristics of a semiconductor, as the specific CNT, single-layer CNT having excellent characteristics of a semiconductor is preferable.

The type of CNT is as described in the section of the raw material CNT which will be described later.

In view of further improving the electric conductivity of the conductive film, the thermoelectric conversion layer, and the like, an intensity ratio G/D (hereinafter, referred to as “G/D ratio”) between a G-band and a D-band in a Raman spectrum of the specific CNT is preferably equal to or higher than 30, and more preferably equal to or higher than 40. The upper limit of the G/D ratio is about 200 for example. It is preferable that a modification treatment, which will be described later, is performed under the condition that makes the G/D ratio of the specific CNT fall into the above range.

(Method for Manufacturing Specific CNT)

Examples of the method for manufacturing the specific CNT include a method of performing a modification treatment on raw material CNT (herein, the raw material CNT means CNT in which the content of oxygen atoms does not satisfy 0.5 to 5.0 atm %) such that the surface of the raw material CNT is modified with an oxygenic functional group.

The oxygenic functional group means a functional group containing oxygen atoms. Examples of the oxygenic functional group include a hydroxyl group, a carbonyl group, a carboxy group, an epoxy group, a formyl group, and the like.

The method of the modification treatment is not particularly limited as long as the content of oxygen in the raw material CNT can be adjusted to fall into the above range. Examples thereof include the following treatment.

Calcination Treatment

In a case where a calcination treatment is performed as the modification treatment, for example, a method of calcining the raw material CNT in an air flow may be used. The calcination temperature is not particularly limited. For example, the calcination temperature is 300° C. to 800° C., preferably 400° C. to 700° C., more preferably 450° C. to 650° C., and even more preferably 450° C. to 550° C. The calcination time is not particularly limited. For example, the calcination time is 5 to 720 minutes, preferably 15 to 600 minutes, and more preferably 60 to 550 minutes. By the calcination treatment, oxygen atoms are introduced into the raw material CNT. However, in a case where the amount of the oxygen atoms introduced is too large, sometimes the G/D ratio, which will be described later, of the specific CNT to be manufactured is reduced. Accordingly, it is desirable that the calcination treatment is performed under the condition that makes the G/D ratio of the specific CNT to be manufactured becomes equal to or higher than 30.

Plasma Treatment

In a case where a plasma treatment is performed as the modification treatment, although there is no particular limitation on a raw material gas and pressure adopted for the plasma treatment, it is preferable that the plasma treatment is performed in a vacuum atmosphere in an oxygen gas flow.

Oxidation Treatment Using Oxidant

In a case where an oxidation treatment using an oxidant is performed as the modification treatment, the oxidant is not particularly limited. Examples of the oxidant include hydrogen peroxide, m-chloroperbenzoic acid (m-CPBA), peracetic acid, potassium permanganate, sulfuric acid, nitric acid, and the like.

For example, the oxidation treatment may be performed by a method of immersing the raw material CNT in a solution containing an oxidant.

The treatment temperature is not particularly limited. For example, the treatment temperature is −80° C. to 200° C., preferably 0° C. to 100° C., and more preferably 20° C. to 100° C. The immersion time is not particularly limited. For example, the immersion time is 5 to 720 minutes, and preferably 10 to 300 minutes.

(Raw Material CNT)

Hereinafter, the raw material CNT which can be used in the method for manufacturing the specific CNT will be described.

Generally, CNT includes single-layer CNT formed of one sheet of carbon film (graphene sheet) wound in the form of a cylinder, double-layer CNT formed of two graphene sheets wound in the form of concentric circles, and multilayered CNT formed of a plurality of graphene sheets wound in the form of concentric circles. In the present invention, as the raw material CNT, each of the single-layer CNT, the double-layer CNT, and the multilayered CNT may be used singly, or two or more kinds thereof may be used in combination. Particularly, for the uses that require the characteristics of a semiconductor, the single-layer CNT and the double-layer CNT are preferably used, and the single-layer CNT is more preferably used.

The single-layer CNT may be semiconductive or metallic, and both the semiconductive CNT and metallic CNT may be used in combination. Furthermore, the raw material CNT may be CNT containing a metal and the like or CNT containing fullerene molecules and the like (particularly, CNT containing fullerene is called pivot).

The raw material CNT can be manufactured by an arc discharge method, a chemical vapor deposition (CVD) method, a laser-ablation method, and the like. The raw material CNT may be obtained by any method, but it is preferable to use raw material CNT obtained by the arc discharge method and the CVD method.

It is also preferable the raw material CNT has undergone a purification treatment. At the time of manufacturing CNT, fullerene, graphite, and amorphous carbon are also generated as by-products in some cases. The raw material CNT may be purified so as to remove the by-products. The CNT purification method is not particularly limited, and examples thereof include methods such as washing, centrifugation, filtration, oxidation, and chromatography. In addition, an acid treatment using nitric acid, sulfuric acid, and the like and an ultrasonic treatment are also effective for removing impurities. Furthermore, from the viewpoint of improving purity, it is more preferable to separate and remove impurities by using a filter.

CNT obtained after purification can be directly used as the raw material CNT. Generally, CNT is generated in the form of strings. Therefore, the generated CNT may be used as the raw material CNT after being cut in the desired length according to the purpose. By an acid treatment using nitric acid, sulfuric acid, or the like, an ultrasonic treatment, a freezing and pulverizing method, and the like, CNT can be cut in the form of short fiber. From the viewpoint of improving purity, it is also preferable to collectively separate CNT by using a filter.

In the present invention, not only cut CNT but also CNT prepared in the form of short fiber can also be used as the raw material CNT.

The average length of raw material CNT is not particularly limited. However, from the viewpoint of ease of manufacturing, film formability, electric conductivity, and the like, the average length of the raw material CNT is preferably 0.01 to 1,000 μm, and more preferably 0.1 to 100 μm.

In a case where single-layer CNT is used as the raw material CNT, the diameter of the single-layer CNT is not particularly limited. However, from the viewpoint of durability, film formability, electric conductivity, and characteristics of a semiconductor (thermoelectric performances), the diameter of the single-layer CNT is preferably 0.5 to 4.0 nm, more preferably 0.6 to 3.0 nm, and even more preferably 0.7 to 2.0 nm.

It is preferable that defects in the raw material CNT are reduced. The used CNT includes defective CNT in some cases. The defect of CNT results in the deterioration of the electric conductivity of the conductive film, the thermoelectric conversion layer, and the like. Therefore, it is preferable to reduce the defect. The amount of the defect of CNT can be estimated by the G/D ratio. In a case where a CNT material has a high G/D ratio, the CNT material can be estimated as having a small amount of defects. Particularly, in a case where single-layer CNT is used as the raw material CNT, the G/D ratio in the raw material CNT is preferably equal to or higher than 30, and more preferably equal to or higher than 40. The upper limit of the G/D ratio in the raw material CNT is about 200 for example.

(Calculation of Diameter of Single-Layer CNT)

The diameter of the single-layer CNT described in the present specification is evaluated by the following method. That is, a Raman spectrum of the single-layer CNT is measured using excitation light of 532 nm (excitation wavelength: 532 nm), and by a shift co (RBM) (cm⁻¹) of a radial breathing mode (RBM), the diameter of the single-layer CNT is calculated using the following calculation equation. The value of a maximum peak in the RBM mode is adopted as ω.

Diameter (nm)=248/ω(RBM) Calculation equation:

From the viewpoint of electric conductivity, the content of the specific CNT in the conductive film with respect to the total mass of the conductive film is preferably 10% to 95% by mass, more preferably 10% to 90% by mass, even more preferably 30% to 85% by mass, particularly preferably 50% to 80% by mass, and most preferably 52% to 80% by mass.

One kind of specific CNT may be used singly, or two or more kinds of specific CNT may be used in combination. In a case where two or more kinds of specific CNT is used in combination, the total content thereof is preferably within the above range.

Furthermore, the conductive film may contain other CNT in addition to the specific CNT. In a case where the conductive film contains other CNT in addition to the specific CNT, the content of the specific CNT with respect to the total amount of CNT in the conductive film is preferably equal to or greater than 50% by mass, more preferably equal to or greater than 70% by mass, even more preferably equal to or greater than 90% by mass, and particularly preferably 100% by mass.

<Specific Insulating Polymer>

The specific insulating polymer is an insulating polymer having a polar group.

In the present specification, “insulating” means that the electric conductivity is equal to or lower than 10⁻⁶ S/m.

Examples of the polar group include monovalent groups such as a OH group, an NH₂ group, an NHR group (R represents an aromatic or aliphatic hydrocarbon), a COOH group, a CHO group, a CONH₂ group, a NHOH group, a SO₃H group (sulfonic acid group), a S(═O)OH group, and a —OP(═O)OH₂ group (phosphoric acid group) and divalent groups such as —NHCO—, —NHSO₂—, —NH—, —CONHCO—, —SO₂NHSO₂—, —NH—NH—, —C(═O)— (carbonyl group), —C(═O)O—, —S(═O)—, and —ROR— (ether group; R's each independently represent a divalent aromatic hydrocarbon or a divalent aliphatic hydrocarbon. Here, two R's may be the same as or different from each other). As the polar group, acidic groups such as a hydroxyl group, a carboxy group, and a sulfonic acid group are preferable, and a hydroxyl group or a carboxy group is more preferable.

Examples of the specific insulating polymer include carboxymethyl cellulose, carboxyethyl cellulose, methyl cellulose, ethyl cellulose, hydroxymethyl cellulose, hydroxyethyl cellulose, methyl hydroxypropyl cellulose, hydroxypropyl methylcellulose, crystalline cellulose, xanthan gum, guar gum, hydroxyethyl guar gum, carboxymethyl guar gum, gum tragacanth, locust bean gum, tamarind seed gum, psyllium seed gum, quince seeds, carrageenan, galactan, gum Arabic, pectin, pullulan, mannan, glucomannan, starch, curdlan, chondroitin sulfate, dermatan sulfate, glycogen, heparan sulfate, hyaluronic acid, keratan sulfate, chondroitin, mucoitin sulfate, dextran, keratosulfate, succinoglucan, karonin acid, alginic acid, propylene glycol alginate, macrogol, chitin, chitosan, carboxymethyl chitin, gelatin, agar, polyvinyl alcohol, polyvinyl pyrrolidone, polyhydroxystyrene, a carboxyvinyl polymer, an alkyl-modified carboxyvinyl polymer, polyacrylic acid, an acrylic acid/alkyl methacrylate copolymer, polyacrylonitrile, a (hydroxyethyl acrylate/sodium acryloyldimethyltaurate) copolymer, an (ammonium acryloyldimethyltaurate/vinyl pyrrolidone) copolymer, nylon, polyethylene terephthalate, polystyrene sulfonate, chemically modified starch, bentonite, xylan, and the like.

In a case where the polar group is an acidic group such as a carboxy group or the sulfonic acid group, the polar group may partially or totally become a salt such as a sodium salt, a potassium salt, or an ammonium salt.

Furthermore, cellulose nanofiber can also be used.

The specific insulating polymer is preferably a water-soluble polymer because then the dispersibility thereof is further improved. The water-soluble polymer means a polymer having a solubility (25° C.) equal to or higher than 1 g/L in water.

In view of further improving the interaction with the specific CNT, the water-soluble polymer is preferably polysaccharides, and more preferably polysaccharides having a carboxy group or a sulfonic acid group or polysaccharides having a salt of a carboxy group or a sulfonic acid group.

As the polysaccharides, cellulose or cellulose derivatives are preferable.

Examples of the cellulose or the cellulose derivatives having a carboxy group or a sulfonic acid group and the cellulose or the cellulose derivatives having a salt of a carboxy group or a sulfonic acid group include caboxymethyl cellulose, sodium carboxymethyl cellulose, carboxyethyl cellulose, sodium carboxyethyl cellulose, and the like.

The weight-average molecular weight of the specific insulating polymer is not particularly limited. However, from the viewpoint of dispersion stability, the weight-average molecular weight is preferably 1,000 to 1,200,000, and more preferably 1,000 to 800,000. The weight-average molecular weight of the specific insulating polymer can be checked using gel permeation chromatography (GPC).

More specifically, regarding the GPC measurement method, an object is dissolved in 100 mM aqueous sodium nitrate solution, and by using a high-performance GPC device (for example, HLC-8220GPC (manufactured by Tosoh Corporation)), the weight-average molecular weight thereof can be calculated and expressed in terms of polyethylene oxide. The conditions of the GPC measurement are as below.

| | |
|---|---|
| Column: manufactured by Tosoh | TSKGEL G5000PWXL |
| Corporation | TSKGEL G4000PWXL |
| | TSKGEL G2500PWXL |
| Column temperature: 40° C. | |
| Flow rate: 1 mL/min | |
| Eluent: 100 mM aqueous sodium | |
| nitrate solution | |

In the conductive film, the content of the specific insulating polymer with respect to the content of the specific CNT is 10% to 100% by mass. In the conductive film, the content of the specific insulating polymer with respect to the content of the specific CNT is preferably 20% to 100% by mass, and more preferably 30% to 85% by mass.

From the viewpoint of electric conductivity and thermal conductivity, the content of the specific insulating polymer in the conductive film with respect to the total mass of the conductive film is preferably 5% to 50% by mass, more preferably 15% to 50% by mass, and even more preferably 20% to 47% by mass.

One kind of specific insulating polymer may be used singly, or two or more kinds of specific insulating polymers may be used in combination. In a case where two or more kinds of specific insulating polymers are used in combination, the total content thereof is preferably within the above range.

As described above, in the conductive film, the periphery of the specific CNT is considered covered with the film formed of the specific insulating polymer. “Covered” mentioned herein includes both the aspect in which the specific insulating polymer coats a portion of the specific CNT and aspect in which the specific insulating polymer coats the entirety of the specific CNT.

In view of further improving electric conductivity, the thickness of the film formed of the specific insulating polymer is preferably about 1 to 30 nm.

In a composition, which will be described later, and the conductive film, the specific CNT is present by forming a bundle structure in many cases by the interaction such as the Van der Walls force between a plurality of CNT rather than being present as independent CNT. It is considered that the specific insulating polymer may cover the periphery of the bundle structure. The inventors of the present invention observed the diameter of the bundle of the specific CNT before and after being mixed with the specific insulating polymer by using SEM. As a result, it has been confirmed that the diameter of the bundle after being mixed with the specific insulating polymer is larger than (100% to 200% of) the diameter of the bundle before being mixed with the specific insulating polymer.

Accordingly, the thickness of the film formed of the specific insulating polymer can be obtained by subtracting the thickness of the bundle structure, which is not yet coated, from the thickness of the bundle structure coated with the specific insulating polymer. The bundle structure which is not yet coated means a bundle structure obtained by removing the specific insulating polymer contained in the bundle structure coated with the specific insulating polymer. For example, in a case where the specific insulating polymer is a water-soluble polymer, the water-soluble polymer can be removed by being dissolved in water.

<Optional Components>

The conductive film may contain other components (a dopant, a dispersant (surfactant), an antioxidant, a light-fast stabilizer, a heat-resistance stabilizer, a plasticizer, and the like) in addition to the specific CNT and the specific insulating polymer. The dispersant may be used at the time of manufacturing the conductive film. From the viewpoint of improving electric conductivity, the smaller the content of the dispersant, the better. It is preferable that the conductive film substantially does not contain the dispersant.

<Thickness of Conductive Film>

The average thickness of the conductive film according to the embodiment of the present invention is not limited because it is appropriately changed according to the use. However, in a case where the conductive film is applied to a thermoelectric conversion layer, from the viewpoint of imparting electric conductivity and causing a temperature difference, the average thickness of the conductive film is preferably 0.1 to 500 μm, more preferably 2 to 300 μm, even more preferably 3 to 200 μm, and particularly preferably 5 to 100 μm.

The average thickness of the conductive film is determined by measuring the thickness of the conductive film at 10 random spots and calculating the arithmetic mean thereof.

[Method for Manufacturing Conductive Film]

The method for manufacturing the conductive film is not particularly limited, and examples thereof include a manufacturing method including a step 1 to a step 3 described below.

Step 1: a step of performing a modification treatment on CNT (raw material CNT) such that the content of oxygen atoms becomes 0.5 to 5.0 atm % (modification treatment step)

Step 2: a step of obtaining a composition which contains the specific CNT obtained by the step 1 and specific insulating polymer and in which the content of the insulating polymer with respect to the content of the carbon nanotubes is 10% to 100% by mass (composition forming step)

Step 3: a step of forming a conductive film on a substrate by using the composition (film forming step)

(Step 1)

The step 1 is a step of performing a modification treatment such that the content of oxygen atoms in CNT (raw material CNT) becomes 0.5 to 5.0 atm %. That is, the step 1 is a step of manufacturing the specific CNT.

As described above, examples of the method for manufacturing the specific CNT include a method of performing a calcination treatment, a plasma treatment, an oxidation treatment using an oxidant, and the like such that the surface of the raw material CNT is modified with an oxygenic functional group.

(Step 2)

The step 2 is a step of obtaining a composition which contains the specific CNT obtained by the step 1 and the specific insulating polymer and in which the content of the insulating polymer with respect to the content of the carbon nanotubes is 10% to 100% by mass.

First, the components contained in the composition will be described, and then the method for preparing the composition will be described.

(1) Specific CNT

The definition, the specific examples, and the suitable aspects of the specific CNT are as described above. The content of the specific CNT in the composition is not particularly limited, but is preferably 0.1% to 20% by mass and more preferably 0.5% to 10% by mass with respect to the total amount of the composition. Furthermore, the content of the specific CNT with respect to the solid contents in the composition is preferably 1% to 95% by mass, more preferably 1% to 90% by mass, even more preferably 5% to 70% by mass, and particularly preferably 10% to 50% by mass. The solid contents mean the components forming the conductive film and do not include solvents.

(2) Specific Insulating Polymer

The definition, the specific examples, and the suitable aspects of the specific insulating polymer are as described above. The content of the specific insulating polymer in the composition is not particularly limited, but is preferably 0.01% to 20% by mass and more preferably 0.05% to 10% by mass with respect to the total amount of the composition. Furthermore, the content of the specific insulating polymer with respect to the solid contents in the composition is preferably 0.1% to 50% by mass, more preferably 0.5% to 50% by mass, and even more preferably 1% to 40% by mass. The solid contents mean the components forming the conductive film and do not include solvents.

In the composition, the content of the specific insulating polymer with respect to the content of the specific CNT is 10% to 100% by mass, preferably 20% to 100% by mass, and more preferably 30% to 85% by mass.

(3) Dispersion Medium

It is preferable that the composition contains a dispersion medium in addition to the specific CNT and the specific insulating polymer.

The dispersion medium (solvent) is not limited as long as it can disperse the specific CNT, and water, an organic solvent, and a mixed solvent of these can be used. Examples of the organic solvent include an alcohol-based solvent, an aliphatic halogen-based solvent such as chloroform, an aprotic polar solvent such as dimethylformamide (DMF), N-methylpyrrolidone (NMP), or dimethylsulfoxide (DMSO), an aromatic solvent such as chlorobenzene, dichlorobenzene, benzene, toluene, xylene, mesitylene, tetralin, tetramethylbenzene, or pyridine, a ketone-based solvent such as cyclohexanone, acetone, or methyl ethyl ketone, an ether-based solvent such as diethyl ether, tetrahydrofuran (THF), t-butyl methyl ether, dimethoxyethane, or diglyme, an ester-based solvent such as ethyl acetate or butyl acetate, and the like.

One kind of dispersion medium can be used singly, or two or more kinds of dispersion media can be used in combination.

It is preferable that the dispersion medium is deaerated in advance. The dissolved oxygen concentration in the dispersion medium is preferably equal to or lower than 10 ppm. Examples of deaeration methods include a method of irradiating the dispersion medium with ultrasonic waves under reduced pressure, a method of performing bubbling of an inert gas such as argon, and the like.

In a case where a medium other than water is used as the dispersion medium, it is preferable that the medium is dehydrated in advance. The amount of moisture in the dispersion medium is preferably equal to or smaller than 1,000 ppm, and more preferably equal to or smaller than 100 ppm. As the method for dehydrating the dispersion medium, it is possible to use known methods such as a method of using a molecular sieve and distillation.

The content of dispersant in the composition with respect to the total amount of the composition is preferably 50% to 99.9% by mass.

(4) Other Components

The composition may contain a binder, a dispersant (surfactant), an antioxidant, a light-fast stabilizer, a heat-resistance stabilizer, a plasticizer, and the like in addition to the components described above.

From the viewpoint of application to a thermoelectric conversion layer, the composition may contain a dopant.

In the atmosphere, the specific CNT exhibits the characteristics of a p-type semiconductor. Therefore, in a case where a conductive film formed of the specific CNT and the specific insulating polymer is used as a thermoelectric conversion layer, generally, the thermoelectric conversion layer functions as a p-type thermoelectric conversion layer. Meanwhile, in a case where the composition contains a dopant for a change to an n-type as a dopant, the obtained conductive film can function as an n-type thermoelectric conversion layer. As the dopant for a change to an n-type, known ones can be used.

The composition may contain a dispersant (surfactant).

Examples of the dispersant (surfactant) include known surfactants (a cationic surfactant, an anionic surfactant, a nonionic surfactant, and the like). Among these, an anionic surfactant is preferable, and sodium deoxycholate, sodium cholate, or sodium dodecylbenzene sulfonate is more preferable.

The content of the dispersant with respect to the total amount of the composition is preferably 0.1% to 20% by mass, and more preferably 1% to 10% by mass.

The composition may further contain an antioxidant, a light-fast stabilizer, a heat-resistance stabilizer, a plasticizer, and the like.

Examples of the antioxidant include IRGANOX 1010 (manufactured by Ciba-Geigy Japan Limited), SUMILIZER GA-80 (manufactured by Sumitomo Chemical Co., Ltd.), SUMILIZER GS (manufactured by Sumitomo Chemical Co., Ltd), SUMILIZER GM (manufactured by Sumitomo Chemical Co., Ltd.), and the like.

Examples of the light-fast stabilizer include TINUVIN 234 (manufactured by BASF SE), CHIMASSORB 81 (manufactured by BASF SE), CYASORB UV-3853 (manufactured by SUN CHEMICAL COMPANY LTD.), and the like.

Examples of the heat-resistance stabilizer include IRGANOX 1726 (manufactured by BASF SE).

Examples of the plasticizer include ADK CIZER RS (manufactured by ADEKA CORPORATION) and the like.

<<Preparation Method of Composition>>

The composition can be prepared by mixing together the components described above. The composition is preferably prepared by mixing together the dispersion medium, the specific CNT, the specific insulating polymer, and other components which are used if desired, and dispersing the specific CNT.

The preparation method of the composition is not particularly limited, and can be performed using a general mixing device or the like at room temperature under normal pressure. For example, the composition may be prepared by dissolving or dispersing the components in a solvent by means of stirring, shaking, or kneading. In order to accelerate the dissolution and dispersion, an ultrasonic treatment may be performed.

Furthermore, it is possible to improve the dispersibility of the specific CNT by means of heating the solvent to a temperature that is equal to or higher than room temperature and equal to or lower than the boiling point in the aforementioned dispersion step, extending the dispersion time, increasing the intensity of stirring, shaking, kneading, or ultrasonic waves applied, and the like.

(Step 3)

The step 3 is a step of forming a conductive film on a substrate by using the composition obtained by the step 2.

The method for forming a conductive film on a substrate is not particularly limited, and examples thereof include a coating method.

The method for coating a substrate with the composition is not particularly limited, and it is possible to use known coating methods such as a spin coating method, an extrusion die coating method, a blade coating method, a bar coating method, a screen printing method, a stencil printing method, a metal mask printing method, a roll coating method, a curtain coating method, a spray coating method, a dip coating method, and an ink jet method.

If necessary, a drying step is performed after coating. For example, by blowing hot air to the conductive film, the solvent can be volatilized and dried.

In a case where the composition contains a dispersant (for example, a surfactant such as sodium deoxycholate), it is preferable to remove the dispersant from the coating film obtained by drying described above. Compared to a conductive film containing the dispersant, a conductive film formed by removing the dispersant from the coating film exhibits higher electric conductivity. Therefore, it is preferable to remove the dispersant from the coating film.

The dispersant can be removed from the coating film obtained by drying, for example, by a method of immersing the coating film in water or an organic solvent which can dissolve the dispersant without dissolving the specific CNT and the specific insulating polymer. In a case where the dispersant is a surfactant such as sodium deoxycholate, as an organic solvent for removing the dispersant, it is possible to use methanol, ethanol, propanol, isopropanol, ethylene glycol, propylene glycol, acetone, 2-butanone, propylene glycol 1-monomethyl ether 2-acetate, 1-methoxy-2-propanol, dimethyl sulfoxide, butanol, sec-butanol, isobutyl alcohol, tert-butanol, glycerin, acetonitrile, N,N-dimethylformamide, N,N-dimethylacetamide, tetrahydrofuran, 1,4-dioxane, 1,3-dimethyl-2-imidazolidinone, N-methylpyrrolidone, N-ethylpyrrolidone, methyl carbitol, butyl carbitol, methyl acetate, ethyl acetate, cyclohexanone, and the like. The immersion time is no particularly limited, but is 5 minutes to 24 hours for example.

<<Substrate>>

The conductive film according to the embodiment of the present invention exhibits high adhesiveness with respect to both the polar substrate and non-polar substrate. Therefore, the substrate is not particularly limited.

Examples of the substrate include a resin substrate, a metal substrate, a ceramic substrate, a glass substrate, and the like.

Examples of the materials of the resin substrate include a polyimide-based resin, a polyether sulfone-based resin, a poly(meth)acrylic resin, a polyurethane-based resin, a polyester-based resin (for example, polyethylene terephthalate, polyethylene naphthalate, and the like), a polycarbonate-based resin, a polysulfone-based resin, a polyamide-based resin, a polyarylate-based resin, a polyolefin-based resin, a cellulose-based resin, a polyvinyl chloride-based resin, a cycloolefin-based resin, and the like.

[Thermoelectric Conversion Layer]

The conductive film can be used as a thermoelectric conversion layer.

In a case where the conductive film is applied to a thermoelectric conversion layer, the thermoelectric conversion layer exhibits high electric conductivity and low thermal conductivity, and consequently, the figure of merit Z is excellent.

The conductive film can be applied to both the p-type thermoelectric conversion layer and n-type thermoelectric conversion layer. In the atmosphere, the specific CNT exhibits the characteristics of a p-type semiconductor. Therefore, the conductive film formed of the specific CNT and the specific insulating polymer generally functions as a p-type thermoelectric conversion layer. Meanwhile, as will be described later, an n-type thermoelectric conversion layer can be formed by performing doping (doping for a change to an n-type) for the conductive film. Furthermore, as described above, in a case where a conductive film is formed of the composition containing an n-type dopant, the obtained conductive film functions as an n-type thermoelectric conversion layer.

Hereinafter, doping (doping for a change to an n-type) for the conductive film will be described.

(Doping for Conductive Film)

The doping for the conductive film is not particularly limited, and can be performed, for example, by a method of immersing the conductive film in a solution obtained by dissolving a dopant for a change to an n-type in a solvent. Specifically, as the solvent, for example, it is possible to use the same solvents as the solvents used in the composition described above.

In the conductive film, the content of the dopant for a change to an n-type with respect to the content of the specific CNT is preferably 0.01% to 100% by mass, and more preferably 0.1% to 50% by mass.

After the doping, if necessary, a drying step is performed. For example, by blowing hot air to the conductive film, the solvent can be volatilized and dried.

[Thermoelectric Conversion Element and Thermoelectric Conversion Module]

The constitution of the thermoelectric conversion element according to the embodiment of the present invention is not particularly limited as long as the thermoelectric conversion element comprises the aforementioned thermoelectric conversion layer. For example, the thermoelectric conversion element according to the embodiment of the present invention comprises the aforementioned thermoelectric conversion layer and an electrode pair which is electrically connected to the thermoelectric conversion layer. It is preferable that the thermoelectric conversion layer functions as a p-type thermoelectric conversion layer. That is, it is preferable that the thermoelectric conversion element comprises the aforementioned thermoelectric conversion layer as a p-type thermoelectric conversion layer.

The constitution of the thermoelectric conversion module according to an embodiment of the present invention is not particularly limited as long as the thermoelectric conversion module comprises a plurality of thermoelectric conversion elements described above.

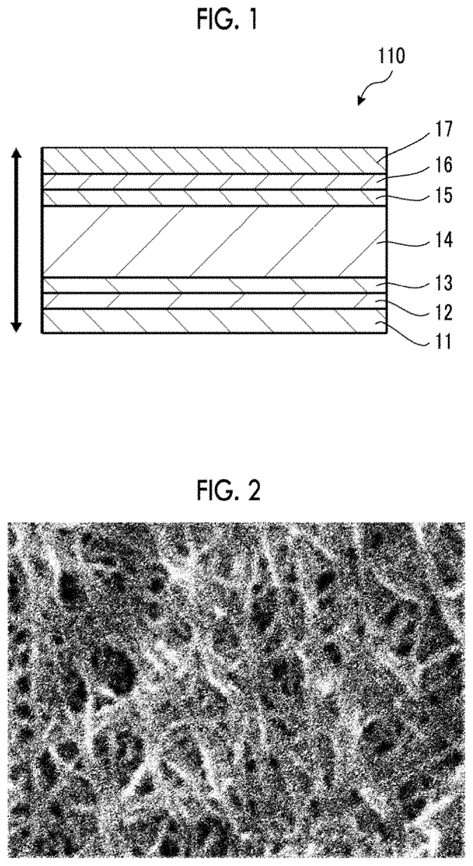

Hereinafter, an example of the embodiment of the thermoelectric conversion element will be described with reference to FIG. 1.

A thermoelectric conversion element 110 shown in FIG. 1 comprises a first substrate 12, a pair of electrodes including a first electrode 13 and a second electrode 15 on the first substrate 12, and a thermoelectric conversion layer 14 which is between the first electrode 13 and the second electrode 15 and contains the specific CNT and the specific insulating polymer at a predetermined quantitative ratio. On the other surface of the second electrode 15, a second substrate 16 is disposed. On the outside of the first substrate 12 and the second substrate 16, metal plates 11 and 17 facing each other are disposed.

Hereinafter, each of the members constituting the thermoelectric conversion element will be specifically described.

<Substrate>

As the substrates in the thermoelectric conversion element, substrates such as glass, transparent ceramics, and a plastic film can be used. In the thermoelectric conversion element described above, it is preferable that the substrate has flexibility. Specifically, it is preferable that the substrate has such flexibility that the substrate is found to have an MIT folding endurance equal to or greater than 10,000 cycles by a measurement method specified by ASTM D2176. As the substrate has such flexibility, a plastic film is preferable, and specific examples thereof include a polyester film such as polyethylene terephthalate, polyethylene isophthalate, polyethylene naphthalate, polybutylene terephthalate, poly(1,4-cyclohexylenedimethyleneterephthalate), polyethylene-2,6-naphthalenedicarboxylate, or a polyester film of bisphenol A and isophthalic and terephthalic acids, a polycycloolefin film such as a ZEONOR film (trade name, manufactured by ZEON CORPORATION), an ARTON film (trade name, manufactured by JSR Corporation), or SUMILITE FS1700 (trade name, manufactured by Sumitomo Bakelite Co. Ltd.), a polyimide film such as KAPTON (trade name, manufactured by DU PONT-TORAY CO., LTD.), APICAL (trade name, manufactured by Kaneka Corporation), UPILEX (trade name, manufactured by UBE INDUSTRIES, LTD.), or POMIRAN (trade name, manufactured by Arakawa Chemical Industries, Ltd.), a polycarbonate film such as PUREACE (trade name, manufactured by TEIJIN LIMITED) or ELMEC (trade name, manufactured by Kaneka Corporation), a polyether ether ketone film such as SUMILITE FS1100 (trade name, manufactured by Sumitomo Bakelite Co. Ltd.); a polyphenyl sulfide film such as TORELINA (trade name, manufactured by TORAY INDUSTRIES, INC.); and the like. From the viewpoint of ease of availability, heat resistance (preferably equal to or higher than 100° C.), and economic feasibility, commercial polyethylene terephthalate, polyethylene naphthalate, various polyimide or polycarbonate films, and the like are preferable.

From the viewpoint of handleability, durability, and the like, the thickness of the substrate is preferably 5 to 3,000 μm, more preferably 5 to 500 μm, even more preferably 5 to 100 μm, and particularly preferably 5 to 50 μm. In a case where the thickness of the substrate is within the above range, a temperature difference can be effectively caused in the thermoelectric conversion layer, and the thermoelectric conversion layer is not easily damaged due to an external shock.

<Electrode>

Examples of electrode materials forming the electrodes in the thermoelectric conversion element include a transparent electrode material such as Indium-Tin-Oxide (ITO) or ZnO, a metal electrode material such as silver, copper, gold, nickel, or aluminum; a carbon material such as CNT or graphene; and an organic material such as poly(3,4-ethylenedioxythiophene) (PEDOT)/polystyrene sulfonate (PSS), or PEDOT/tosylate (Tos). The electrodes can be formed using a conductive paste in which conductive fine particles of gold, silver, copper, or carbon are dispersed, solder, a conductive paste containing metal nanowires of gold, silver, copper, or aluminum, and the like.

<Metal Plate>

Metal materials forming a metal plate in the thermoelectric conversion element are not particularly limited, and the metal plate may be formed of metal materials generally used in thermoelectric conversion elements.

[Composition]

The composition according to an embodiment of the present invention contains the specific CNT and the specific insulating polymer, in which the content of the specific insulating polymer with respect to the content of the carbon nanotubes is 10% to 100% by mass.

The composition according to the embodiment of the present invention has the same aspect as the composition described in the step 2 of the method for manufacturing the conductive film described above.

### EXAMPLES

Hereinafter, the present invention will be more specifically described based on examples. The materials, the amount and the ratio of the materials used, the details of a treatment, the procedure of a treatment, and the like shown in the following examples can be appropriately changed as long as the gist of the present invention is maintained. Therefore, the scope of the present invention is not limited to the following examples.

### Example 1

(Modification Treatment for CNT)

Sing-layer CNT (3 g, TUBALL manufactured by OCSiAl) was put into a crucible and calcined for 300 minutes at 500° C. in a desktop muffle furnace (KDF S-80 manufactured by DENKEN Co., ltd.) in an air flow.

(Measurement of Content of Oxygen Atoms)

The content of oxygen atoms in the specific CNT was measured by the following method by using XPS. Specifically, By XPS, “peak area A of oxygen atoms (is) derived from C—O or C═O at about 531 eV” and “peak area B of carbon atoms (is) at about 285 eV” were determined. Based on the obtained peak areas, atomic percent was calculated by the following Equation (1). The results are shown in Table 1.

Content of oxygen atoms (atm %)=(A)/(A+B)×100 Equation (1):

In Equation (1), A represents a peak area of oxygen atoms (Is) derived from C—O or C═O at about 531 Ev, and B represents a peak area of carbon atoms (Is) at about 285 eV.

(Preparation of Dispersion Composition)

CNT (800 mg) having undergone the modification treatment and 400 mL of acetone were mixed together for 5 minutes at 18,000 rpm by using a mechanical homogenizer (manufactured by SMT Corporation, HIGH-FLEX HOMOGENiZER HF93), thereby obtaining a dispersion liquid. The dispersion liquid was filtered under reduced pressure by using a Buchner funnel equipped with filter paper (diameter: 125 mm) and a suction bottle, thereby obtaining a buckypaper film. The obtained film was dried for 30 minutes at 50° C. and then for 30 minutes at 120° C., cut in a size equal to or smaller than 0.3 cm×0.3 cm, and used for preparing a CNT dispersion composition in the next step.

Then, 40 mg of sodium carboxymethyl cellulose (manufactured by Sigma-Aldrich Co. LLC., low-viscosity product) and 1,200 mg of sodium deoxycholate (manufactured by TOKYO CHEMICAL INDUSTRY CO., LTD.) were dissolved in 16 mL of water as a dispersion solvent, and 400 mg of the single-layer CNT cut as described above was added thereto. By using a mechanical homogenizer (manufactured by SMT Corporation, HIGH-FLEX HOMOGENiZER HF93), the composition was mixed for 2 minutes at 1,000 rpm and then for 5 minutes at 5,000 rpm, thereby obtaining a premix. By using a thin film revolution-type high-speed mixer “FILMIX 40-40 model” (manufactured by PRIMIX Corporation), a dispersion treatment was performed on the obtained premix in a constant-temperature tank with a temperature equal to or lower than 10° C. for 2 minutes at a circumferential speed of 10 m/sec and then for 5 minutes at a circumferential speed of 40 m/sec by a high-speed revolution thin film dispersion method. By using a rotation-revolution mixer (manufactured by THINKY CORPORATION, AWATORI RENTARO ARE-310), the obtained dispersion composition was mixed for 30 seconds at 2,000 rpm and defoamed for 30 seconds at 2,200 rpm, thereby preparing a CNT dispersion composition.

(Preparation of Conductive Film)

A sheet of frame (thickness: 0.2 μm) made of Teflon (registered trademark) was bonded to a glass substrate having a thickness of 1.1 mm and a size of 40 mm×50 mm, and the obtained CNT dispersion composition was applied to the area in the frame. Then, the applied CNT dispersion composition was dried for 30 minutes at 50° C. and then for 30 minutes at 120° C., and the substrate was immersed in ethanol for 1 hour so as to remove the dispersant and dried for 30 minutes at 50° C. and then for 150 minutes at 120° C., thereby obtaining a conductive film.

(Preparation of Conductive Film Sample for Measurement)

The obtained conductive film was cut in a size of about 1 cm×1 cm, thereby preparing a conductive film sample for measuring an electric conductivity (σ), a Seebeck coefficient (S), a thermal conductivity (κ), and a figure of merit Z. For each of the examples and the comparative examples which will be described later, the conductive film sample for measurement was prepared in the same manner as in Example 1.

### Examples 2 to 12 and 16 to 20 and Comparative Examples 2 and 3

Conductive films of Examples 2 to 12 and 16 to 20 and Comparative Examples 2 and 3 were prepared by the same method as that in Example 1, except that the conditions were changed to the conditions described in Table 1.

### Example 13

(Modification Treatment for CNT)

By using a rotary vacuum plasma apparatus (YHS-D+S), 10 g of single-layer CNT (TUBALL manufactured by OCSiAl) was treated for 30 minutes under the conditions of oxygen: 200 mL/min, pressure: 100 Pa, power: 250 W, and a rotation speed: 6 rpm.

(Preparation of Dispersion Composition and Conductive Film)

A dispersion composition and a conductive film were prepared in the same manner as in Example 1.

### Example 14

(Modification Treatment for CNT)

Single-layer CNT (800 mg, TUBALL manufactured by OCSiAl) was weighed and put into a 1 L reaction container made of glass, and 400 mL of pure water was added thereto. Aqueous hydrogen peroxide (30 wt %, 400 mL) was further added to the reaction container, and the reactants were allowed to react for 45 minutes at room temperature. After the reaction ended, solid contents were collected by filtration under reduced pressure by using a Buchner funnel, and the obtained solid contents were washed with pure water, thereby collecting CNT having undergone the modification treatment. The obtained CNT was dried for 30 minutes at 50° C. and then for 30 minutes at 120° C.

(Preparation of Dispersion Composition and Conductive Film)

A dispersion composition and a conductive film were prepared in the same manner as in Example 1.

### Example 15

(Modification Treatment for CNT)

Single-layer CNT (800 mg, TUBALL manufactured by OCSiAl) was weighed and put into a 1 L reaction container made of glass, and 800 mL of ethyl acetate was added thereto. m-Chloroperbenzoic acid (m-CPBA, 80 mg) was further added thereto, and the reactants were allowed to react for 45 minutes (oxidation reaction) at 0° C. After the reaction ended, solid contents were filtered under reduced pressure by using a Buchner funnel, and the obtained solid contents were washed with pure water, thereby collecting CNT having undergone the modification treatment. The obtained CNT was dried for 30 minutes at 50° C. and then for 30 minutes at 120° C.

(Preparation of Dispersion Composition and Conductive Film)

A dispersion composition and a conductive film were prepared in the same manner as in Example 1.

### Comparative Example 1

The same operation as that in Example 1 was performed, except that the modification treatment for CNT was not carried out.

### Comparative Example 4

The same operation as that in Example 14 was performed, except that the modification treatment for CNT was carried out at 60° C.

### Comparative Example 5

(Preparation of Dispersion Composition)

CNT (800 mg) having undergone the modification treatment under the same conditions as those in Example 1 and 400 mL of acetone were mixed together for 5 minutes at 18,000 rpm by using a mechanical homogenizer (manufactured by SMT Corporation, HIGH-FLEX HOMOGENiZER HF93), thereby obtaining a dispersion liquid. The dispersion liquid was filtered under reduced pressure by using a Buchner funnel equipped with filter paper (diameter: 125 mm) and a suction bottle, thereby obtaining a buckypaper film. The obtained film was dried for 30 minutes at 50° C. and then for 30 minutes at 120° C., then cut in a size equal to or smaller than 0.3 cm×0.3 cm, and used for preparing a CNT dispersion composition in the next step.

Then, 200 mg of polystyrene (manufactured by Sigma-Aldrich Co. LLC.) was dissolved in 16 mL of dichlorobenzene as a dispersion solvent, and 400 mg of the single-layer CNT cut as described above was added thereto. The composition was subjected to a dispersion treatment by means of milling. By using a rotation-revolution mixer (manufactured by THINKY CORPORATION, AWATORI RENTARO ARE-310), the obtained dispersion composition was mixed for 30 seconds at 2,000 rpm and defoamed for 30 seconds at 2,200 rpm, thereby preparing a CNT dispersion composition.

(Preparation of Conductive Film)

A sheet of frame (thickness: 0.2 μm) made of Teflon (registered trademark) was bonded to a glass substrate having a thickness of 1.1 mm and a size of 40 mm×50 mm, and the obtained CNT dispersion composition was applied to the area in the frame. Then, the applied CNT dispersion composition was dried for 30 minutes at 100° C. and then for 150 minutes at 200° C., thereby obtaining a conductive film.

### Comparative Example 6

The same operation as that in Example 1 was performed, except that the modification treatment (calcination) for CNT was carried out for 300 minutes at 400° C.

### Comparative Example 7

The same operation as that in Example 1 was performed, except that the modification treatment (calcination) for CNT was carried out for 200 minutes at 700° C.

[Evaluation]

<Substrate Adhesiveness>

A sheet of frame (thickness: 0.2 μm) made of Teflon (registered trademark) was bonded to each of the following substrates 1 to 5, and the CNT dispersion composition of each of the examples and comparative examples was applied to the area in the frame. The CNT dispersion composition on the substrate was dried for 30 minutes at 50° C. and then for 30 minutes at 120° C., thereby obtaining a substrate having a conductive film.

For each of the examples and comparative examples, 10 sheets of conductive films described above was prepared for each type of the substrate.

(Type of Substrate)

Substrate 1: polyimide film (manufactured by UBE INDUSTRIES, LTD. (polar substrate))

Substrate 2: glass (polar substrate)

Substrate 3: polyimide film coated with Teflon (registered trademark) (manufactured by Du Pont-Toray Co., Ltd., (non-polar substrate))

Substrate 4: copper foil (manufactured by DENKA ELECTRON CO., LTD. (polar substrate))

Substrate 5: film having a polyimide region/Teflon (registered trademark)-coated polyimide region (hybrid substrate having a polar region and a non-polar region)

The substrate 5, which is a film having polyimide region/Teflon (registered trademark)-coated polyimide region, is a substrate having an interface between polyimide and Teflon (registered trademark)-coated polyimide within the surface, and prepared by bonding a polyimide film and a polyimide film processed with Teflon (registered trademark) to a glass substrate through a double-sided tape.

(Evaluation Method)

By using the obtained conductive film, the substrate adhesiveness was evaluated according to the following procedure.

First, for each substrate, the conductive film was immersed in ethanol for 1 hour. Then, the conductive film having undergone immersion was dried for 30 minutes at 50° C. and then for 150 minutes at 120° C. Thereafter, the dried conductive film was observed, and the substrate adhesiveness thereof was evaluated based on the following evaluation standards.

(Evaluation Standards)

“A”: The conductive film was not peeled from the substrate, and partial peeling of the conductive film from the substrate was not observed.

“B”: The conductive film was not peeled from the substrate, but partial peeling of the conductive film from the substrate was observed at few sites.

“C”: The conductive film was not peeled from the substrate, but partial peeling of the conductive film from the substrate occurred at many sites.

“D”: Among 10 sheets of conductive films, 1 to 4 sheets of conductive films were peeled from the substrate.

“E”: Among 10 sheets of conductive films, 5 or more sheets of conductive films were peeled from the substrate.

<Electric Conductivity (σ)>

By using a thermoelectric characteristic measuring apparatus MODEL RZ2001i (manufactured by OZAWA SCIENCE CO., LTD.), an electric conductivity of the conductive film at about 80° C. and 105° C. was measured. By interpolation, an electric conductivity at 100° C. was calculated. For one example (comparative example), 10 samples were measured, and the average thereof was used.

The electric conductivity was evaluated based on values normalized by the following equation.

(Electric Conductivity (σ))

By adopting Comparative Example 1 as a reference comparative example, a normalized electric conductivity of each of the examples and the comparative examples was determined by the following equation. The evaluation standards are as below. The results are shown in Table 1.

(Normalized electric conductivity)=(electric conductivity of conductive film of each example or each comparative example)/(electric conductivity of conductive film of Comparative Example 1)

<<Evaluation Standards>>

“A”: The normalized electric conductivity was equal to or higher than 1.5.

“B”: The normalized electric conductivity was equal to or higher than 1.3 and less than 1.5.

“C”: The normalized electric conductivity was equal to or higher than 1.1 and less than 1.3.

“D”: The normalized electric conductivity was equal to or higher than 0.9 and less than 1.1.

“E”: The normalized electric conductivity was equal to or higher than 0.7 and less than 0.9.

“F”: The normalized electric conductivity was less than 0.7.

The abbreviations in Table 1 and Table 2 will be described below.

“CMC-Na”: sodium carboxymethyl cellulose (water-soluble polymer)

“PSS-Na”: sodium polystyrene sulfonate (water-soluble polymer)

“CNF”: cellulose nanofiber (water-soluble polymer)

“HEC”: hydroxyethyl cellulose (water-soluble polymer)

“PVA”: polyvinyl alcohol (water-soluble polymer)

“PVP”: polyvinyl pyrrolidone (water-soluble polymer)

“Content of the specific insulating polymer with respect to the content of the specific CNT” in the composition (CNT dispersion composition) used for forming the conductive films in Examples 1 to 20 and Comparative Examples 1 to 7 corresponds to “content of the specific insulating polymer with respect to the content of specific CNT” described in Table 1 and Table 2.

TABLE 1

| | Composition of conductive film | | | | |
|---|---|---|---|---|---|
| | | | | Specific insulating polymer | |
| | Specific CNT | | | | Content of specific |
| | | Content of | | | insulating polymer with |
| | Conditions of | oxygen atoms | G/D | | respect to content of |
| | modification treatment | (atm %) | ratio | Type | specific CNT (% by mass) |
| Example 1 | Calcination 500° C. 300 min | 1.3 | 44 | CMC-Na | 10 |
| Example 2 | Calcination 500° C. 300 min | 1.3 | 44 | CMC-Na | 20 |
| Example 3 | Calcination 500° C. 300 min | 1.3 | 44 | CMC-Na | 30 |
| Example 4 | Calcination 500° C. 300 min | 1.3 | 44 | CMC-Na | 50 |
| Example 5 | Calcination 500° C. 300 min | 1.3 | 44 | CMC-Na | 70 |
| Example 6 | Calcination 500° C. 300 min | 1.3 | 44 | CMC-Na | 85 |
| Example 7 | Calcination 500° C. 300 min | 1.3 | 44 | CMC-Na | 100 |
| Example 8 | Calcination 500° C. 30 min | 0.5 | 49 | CMC-Na | 50 |
| Example 9 | Calcination 500° C. 250 min | 1 | 49 | CMC-Na | 50 |
| Example 10 | Calcination 500° C. 500 min | 2 | 43 | CMC-Na | 50 |
| Example 11 | Calcination 600° C. 200 min | 3 | 41 | CMC-Na | 50 |
| Example 12 | Calcination 600° C. 300 min | 4.9 | 40 | CMC-Na | 50 |
| Example 13 | Plasma | 2.4 | 43 | CMC-Na | 50 |
| Example 14 | Hydrogen peroxide | 1.9 | 45 | CMC-Na | 50 |
| Example 15 | mCPBA | 1.8 | 45 | CMC-Na | 50 |
| Example 16 | Calcination 500° C. 300 min | 1.3 | 44 | PSS-Na | 50 |
| Example 17 | Calcination 500° C. 300 min | 1.3 | 44 | CNF | 50 |
| Example 18 | Calcination 500° C. 300 min | 1.3 | 44 | HEC | 50 |
| Example 19 | Calcination 500° C. 300 min | 1.3 | 44 | PVA | 50 |
| Example 20 | Calcination 500° C. 300 min | 1.3 | 44 | PVP | 50 |
| Comparative | N/A | 0.2 | 49 | CMC-Na | 50 |
| Example 1 | | | | | |
| Comparative | Calcination 500° C. 300 min | 1.3 | 44 | CMC-Na | 150 |
| Example 2 | | | | | |
| Comparative | Calcination 500° C. 300 min | 1.3 | 44 | CMC-Na | 1 |
| Example 3 | | | | | |
| Comparative | Hydrogen peroxide (60° C.) | 5.8 | 32 | CMC-Na | 50 |
| Example 4 | | | | | |
| Comparative | Calcination 500° C. 300 min | 1.3 | 44 | Polystyrene | 50 |
| Example 5 | | | | (non-polar) | |
| Comparative | Calcination 400° C. 300 min | 0.4 | 42 | CMC-Na | 50 |
| Example 6 | | | | | |
| Comparative | Calcination 700° C. 200 min | 6.4 | 30 | CMC-Na | 50 |
| Example 7 | | | | | |

| | Evaluation | | | | | |
|---|---|---|---|---|---|---|
| | Adhesiveness | | | | | |
| | | Polyimide | | | Polyimide-Teflon- | |
| | | processed | Copper | | processed | Electric |
| | Polyimide | with Teflon | foil | Glass | polyimide | conductivity |
| Example 1 | C | C | C | C | C | C |
| Example 2 | B | B | B | B | B | B |
| Example 3 | A | B | A | A | A | A |
| Example 4 | A | B | A | A | A | A |
| Example 5 | A | B | A | A | A | A |
| Example 6 | A | B | A | A | A | A |
| Example 7 | B | B | B | B | B | B |
| Example 8 | B | B | B | B | B | B |
| Example 9 | A | B | A | A | A | A |
| Example 10 | A | B | A | A | A | A |
| Example 11 | A | B | A | A | A | A |
| Example 12 | B | B | B | B | B | B |
| Example 13 | B | C | B | B | C | B |
| Example 14 | B | C | B | B | C | B |
| Example 15 | B | C | B | B | C | B |
| Example 16 | B | C | B | B | C | B |
| Example 17 | B | B | B | B | B | B |
| Example 18 | B | B | B | B | B | B |
| Example 19 | B | C | B | B | C | B |
| Example 20 | B | C | B | B | C | B |
| Comparative | D | E | D | D | E | D |
| Example 1 | | | | | | |
| Comparative | A | E | A | A | E | F |
| Example 2 | | | | | | |
| Comparative | E | C | E | E | E | B |
| Example 3 | | | | | | |
| Comparative | A | E | A | A | E | E |
| Example 4 | | | | | | |
| Comparative | D | E | D | D | E | D |
| Example 5 | | | | | | |
| Comparative | D | E | D | D | E | D |
| Example 6 | | | | | | |
| Comparative | A | E | A | A | E | E |
| Example 7 | | | | | | |

From Table 1, it has been revealed that the conductive film according to the embodiment of the present invention exhibits high adhesiveness with respect to both the non-polar substrate and polar substrate. Furthermore, it is understood that the conductive film according to the embodiment of the present invention has excellent electric conductivity. FIG. 2 shows a SEM image of the conductive film according to the embodiment of the present invention (Example 4).

By comparing Examples 1 to 7 with one another, it has been confirmed that in a case where the content of the specific insulating polymer with respect to the content of the specific CNT is 20% to 100% by mass (preferably 30% to 85% by mass), the substrate adhesiveness and the electric conductivity are further improved.

By comparing Examples 8 to 12 with one another, it has been confirmed that in a case where the content of oxygen atoms in the specific CNT is 1.0 to 3.0 atm %, the substrate adhesiveness and the electric conductivity are further improved. From the results of Examples 8 to 12, it has been confirmed that the smaller the content of oxygen atoms is, the higher the G/D ratio tends to be.

By comparing Example 4 and Examples 13 to 15 with one another, it has been confirmed that in a case where a calcination treatment is performed as a modification treatment, the substrate adhesiveness and the electric conductivity are further improved.

By comparing Example 4 and Examples 16 to 20 with one another, it has been confirmed that in a case where the specific insulating polymer is cellulose or cellulose derivatives (preferably, cellulose or cellulose derivatives having a salt of a carboxy group or a sulfonic acid group), the substrate adhesiveness and the electric conductivity are further improved.

In contrast, from Table 1, it has been revealed that the conductive films of comparative examples exhibit poor adhesiveness with respect to substrates. It is also understood that the conductive films of comparative examples tend to be poor in electric conductivity.

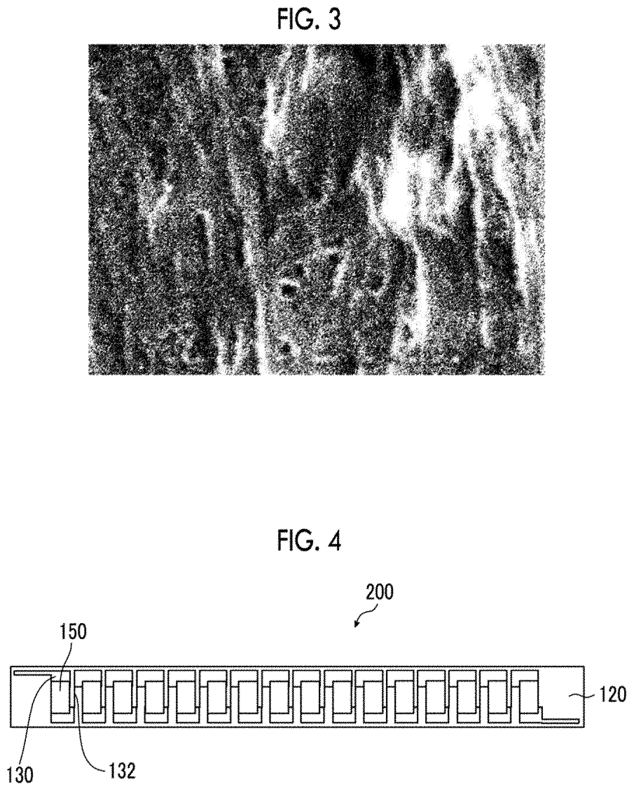

By observing the conductive film of Comparative Example 1 by using SEM, it has been confirmed that the specific insulating polymer is localized without coating the specific CNT. Presumably, this is because the content of oxygen atoms is less than a predetermined range, and the interaction between CNT and the specific insulating polymer is insufficient. FIG. 3 shows a SEM image of the conductive film of Comparative Example 1.

Next, by using the conductive films of Examples 1 to 20 and Comparative Examples 1 to 7, a thermal conductivity (κ) and a figure of merit Z described below were evaluated.

<Seebeck Coefficient (S)>

By using a thermoelectric characteristic measuring apparatus MODEL RZ2001i (manufactured by OZAWA SCIENCE CO., LTD.), a Seebeck coefficient (thermoelectromotive force per absolute temperature of 1 K) of the conductive film at about 80° C. and 105° C. was measured. By interpolation, a Seebeck coefficient at 100° C. was calculated. For one example (comparative example), 10 samples were measured, and the average thereof was used.

<Evaluation of Thermal Conductivity (κ)>

By the following equation, a thermal conductivity (κ) of the conductive film of each of the examples and comparative examples was calculated. For determining the thermal diffusivity, the specific heat, and the density, similarly to the electric conductivity and the Seebeck coefficient, 10 samples were measured for each example (comparative example), and the average thereof was used.

(Thermal conductivity [W/mK])=(specific heat [J/kg·K])×(density [kg/m³])×(thermal diffusivity [m²/s])

“Specific heat” in the above equation was measured by differential scanning calorimetry (DSC method), and “density” was measured by mass/volume. “Thermal diffusivity” was measured using THERMOWAVE ANALYZER TA33 (manufactured by BETHEL Co., Ltd.).

The thermal conductivity (κ) was evaluated based on the value normalized by the equation shown below. Specifically, by adopting Comparative Example 1 as a reference comparative example, a normalized thermal conductivity (hereinafter, referred to as “normalized thermal conductivity” as well) of each of the examples and the comparative examples was calculated by the following equation. The evaluation standards are as below. The results are shown in Table 2.

(Normalized thermal conductivity)=(thermal conductivity of conductive film of each example or each comparative example)/(thermal conductivity of conductive film of Comparative Example 1)

<<Evaluation Standards>>

“A”: The normalized thermal conductivity was less than 0.5.

“B”: The normalized thermal conductivity was equal to or higher than 0.5 and less than 0.7.

“C”: The normalized thermal conductivity was equal to or higher than 0.7 and less than 0.9.

“D”: The normalized thermal conductivity was equal to or higher than 0.9 and less than 1.1.

“E”: The normalized thermal conductivity was equal to or higher than 1.1.

(Evaluation of Figure of Merit Z Ratio)

The figure of merit Z was calculated by the following equation.

(Figure of merit Z)=[(electric conductivity)×(Seebeck coefficient)²]/thermal conductivity

As the electric conductivity, the Seebeck coefficient, and the thermal conductivity, the values obtained by the various measurement methods described above were used.

By using the calculated figure of merit Z of each of the examples and the comparative examples, a normalized figure of merit Z ratio (hereinafter, referred to as “Z ratio” as well) was calculated by the equation shown below. Specifically, the Z ratio of each of the examples and the comparative examples was calculated by the following equation. Comparative Example 1 was used as a reference comparative example. The results are shown in Table 2.

(Z ratio)=(figure of merit Z of thermoelectric conversion layer of each example or each comparative example)/(figure of merit Z of thermoelectric conversion layer of reference comparative example 1)

<<Evaluation Standards>>

“A”: Z ratio is equal to or higher than 3.0.

“B”: Z ratio is equal to or higher than 2.2 and less than 3.0.

“C”: Z ratio is equal to or higher than 1.4 and less than 2.2.

“D”: Z ratio is equal to or higher than 0.6 and less than 1.4.

“E”: Z ratio is less than 0.6.

TABLE 2

| | Composition of conductive film | | | | | | |
|---|---|---|---|---|---|---|---|
| | | | | Specific insulating polymer | | | |
| | Specific CNT | | | | Content of specific | | |
| | | Content of | | | insulating polymer with | Evaluation | |
| | Conditions of | oxygen atoms | G/D | | respect to content of | Thermal | Figure |
| | modification treatment | (atm %) | ratio | Type | specific CNT (% by mass) | conductivity | of merit Z |
| Example 1 | Calcination 500° C. 300 min | 1.3 | 44 | CMC-Na | 10 | C | C |
| Example 2 | Calcination 500° C. 300 min | 1.3 | 44 | CMC-Na | 20 | B | B |
| Example 3 | Calcination 500° C. 300 min | 1.3 | 44 | CMC-Na | 30 | A | A |
| Example 4 | Calcination 500° C. 300 min | 1.3 | 44 | CMC-Na | 50 | A | A |
| Example 5 | Calcination 500° C. 300 min | 1.3 | 44 | CMC-Na | 70 | A | A |
| Example 6 | Calcination 500° C. 300 min | 1.3 | 44 | CMC-Na | 85 | A | A |
| Example 7 | Calcination 500° C. 300 min | 1.3 | 44 | CMC-Na | 100 | A | B |
| Example 8 | Calcination 500° C. 30 min | 0.5 | 49 | CMC-Na | 50 | B | B |
| Example 9 | Calcination 500° C. 250 min | 1 | 49 | CMC-Na | 50 | A | A |
| Example 10 | Calcination 500° C. 500 min | 2 | 43 | CMC-Na | 50 | A | A |
| Example 11 | Calcination 600° C. 200 min | 3 | 41 | CMC-Na | 50 | A | A |
| Example 12 | Calcination 600° C. 300 min | 4.9 | 40 | CMC-Na | 50 | B | B |
| Example 13 | Plasma | 2.4 | 43 | CMC-Na | 50 | B | B |
| Example 14 | Hydrogen peroxide | 1.9 | 45 | CMC-Na | 50 | B | B |
| Example 15 | mCPBA | 1.8 | 45 | CMC-Na | 50 | B | B |
| Example 16 | Calcination 500° C. 300 min | 1.3 | 44 | PSS-Na | 50 | B | B |
| Example 17 | Calcination 500° C. 300 min | 1.3 | 44 | CNF | 50 | B | B |
| Example 18 | Calcination 500° C. 300 min | 1.3 | 44 | HEC | 50 | B | B |
| Example 19 | Calcination 500° C. 300 min | 1.3 | 44 | PVA | 50 | B | B |
| Example 20 | Calcination 500° C. 300 min | 1.3 | 44 | PVP | 50 | B | B |
| Comparative | N/A | 0.2 | 49 | CMC-Na | 50 | D | D |
| Example 1 | | | | | | | |
| Comparative | Calcination 500° C. 300 min | 1.3 | 44 | CMC-Na | 150 | A | E |
| Example 2 | | | | | | | |
| Comparative | Calcination 500° C. 300 min | 1.3 | 44 | CMC-Na | 1 | E | E |
| Example 3 | | | | | | | |
| Comparative | Hydrogen Peroxide (60° C.) | 5.8 | 32 | CMC-Na | 50 | A | D |
| Example 4 | | | | | | | |
| Comparative | Calcination 500° C. 300 min | 1.3 | 44 | Polystyrene | 50 | D | D |
| Example 5 | | | | (non-polar) | | | |
| Comparative | Calcination 400° C. 300 min | 0.4 | 42 | CMC-Na | 50 | D | D |
| Example 6 | | | | | | | |
| Comparative | Calcination 700° C. 200 min | 6.4 | 30 | CMC-Na | 50 | A | E |
| Example 7 | | | | | | | |

From Table 2, it has been confirmed that in a case where the conductive film according to the embodiment of the present invention is used as a thermoelectric conversion layer, the thermoelectric conversion layer exhibits low thermal conductivity and is excellent in the figure of merit Z.

By comparing Examples 1 to 7 with one another, it has been confirmed that in a case where the content of the specific insulating polymer with respect to the content of the specific CNT is 30% to 85% by mass, both the excellent electric conductivity and excellent thermal conductivity are achieved, and consequently, the figure of merit Z is further improved.

From Table 1 and Table 2, it has been confirmed that in a case where the conductive films of comparative examples are used as a thermoelectric conversion layer, both the excellent electric conductivity and excellent thermal conductivity cannot be achieved, and consequently, the figure of merit Z deteriorates.

(Manufacturing of Thermoelectric Conversion Module)

### Example 21

A thermoelectric conversion module of Example 21 was prepared as below.

First, a silver paste was printed on a 1.6 cm (width)×14 cm (length) substrate 120 (polyimide substrate) by screen printing, the printed material of the silver paste was dried for 1 hour at 120° C., and 16 pairs of electrodes 130 and wiring 132 were simultaneously formed. The size of one electrode was 3 mm (width)×2.5 mm (length). Furthermore, in order that sixteen thermoelectric conversion layers 150, which will be described later, were connected to each other in series, a pair of electrodes 130 were connected to each other through silver wiring.

Then, by metal mask printing, the CNT dispersion composition of Example 4 was printed in a size of 3 mm (width)×6 mm (length), thereby forming a coating film. Sixteen coating films were formed at positions where the coating films were connected to a pair of electrodes 130.

The coating film was dried for 30 minutes at 50° C. and then for 30 minutes at 120° C. Thereafter, for each substrate, the coating film was immersed in ethanol for 1 hour, thereby removing the dispersant. Subsequently, the coating film from which the dispersant had been removed was dried for 30 minutes at 50° C. and then for 150 minutes at 120° C., thereby obtaining a thermoelectric conversion module 200 having 16 thermoelectric conversion layers 150.

### Comparative Example 8

A thermoelectric conversion module was obtained in the same manner as in Example 21, except that the CNT dispersion composition of Comparative Example 1 was used.

(Evaluation of Thermoelectric Conversion Module)

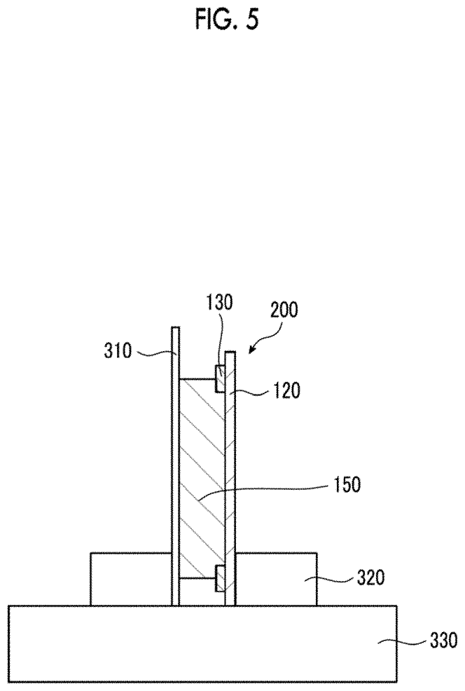

FIG. 5 is a view for illustrating a method for evaluating the thermoelectric conversion modules in examples. As shown in FIG. 5, a power generating layer side of the thermoelectric conversion module 200 was protected with an aramid film 310. Furthermore, the lower portion of the thermoelectric conversion module 200 was fixed by being interposed between copper plates 320 installed on a hot plate 330 such that the lower portion of the thermoelectric conversion module 200 could be efficiently heated.

Then, terminals (not shown in the drawing) of a source meter (manufactured by Keithley Instruments, Inc.) were mounted on extraction electrodes (not shown in the drawing) at both ends of the thermoelectric conversion module 200, and the temperature of the hot plate 330 was caused to remain constant at 100° C. such that a temperature difference was caused in the thermoelectric conversion module 200.

The current-voltage characteristics were measured, and a short-circuit current and an open voltage were measured. From the measured results, an output was calculated by “(Output)=[(Current)×(Voltage)/4]”. As a result, the output was Example 21>Comparative Example 8, which supports the performances of the thermoelectric conversion layer of Example 21.

### EXPLANATION OF REFERENCES

11, 17: metal plate
12: first substrate
13: first electrode
14: thermoelectric conversion layer
15: second electrode
16: second substrate
120: substrate
130: electrode
132: wiring
150: thermoelectric conversion layer
200: thermoelectric conversion module
310: aramid film
320: copper plate
330: hot plate

What is claimed is:

1. A conductive film comprising:
single-layer carbon nanotubes; and
an insulating polymer having a polar group,
wherein a content of oxygen atoms in the single-layer carbon nanotubes is 0.5 to 5.0 atm %,
a content of the insulating polymer with respect to a content of the single-layer carbon nanotubes is 10% to 100% by mass, and
a content of the single-layer carbon nanotubes with respect to a total mass of the conductive film is 50 to 90% by mass.

2. The conductive film according to claim 1,
wherein a G/D ratio of the carbon nanotubes is equal to or higher than 30.

3. The conductive film according to claim 1,
wherein the insulating polymer is a water-soluble polymer.

4. The conductive film according to claim 3,
wherein the water-soluble polymer is polysaccharides.

5. The conductive film according to claim 4,
wherein the polysaccharides are cellulose or cellulose derivatives.

6. A thermoelectric conversion layer comprising:
the conductive film according to claim 1.

7. A thermoelectric conversion element comprising:
the thermoelectric conversion layer according to claim 6.

8. A thermoelectric conversion module comprising:
a plurality of the thermoelectric conversion elements according to claim 7.

9. A method for manufacturing the conductive film according to claim 1, comprising:
a step of performing a modification treatment on single-layer carbon nanotubes such that a content of oxygen atoms becomes 0.5 to 5.0 atm %;
a step of obtaining a composition which contains the single-layer carbon nanotubes, in which the content of oxygen atoms is adjusted by the modification treatment, and an insulating polymer having a polar group and in which a content of the insulating polymer with respect to a content of the single-layer carbon nanotubes is 10% to 100% by mass; and
a step of forming a conductive film on a substrate by using the composition.

10. The conductive film according to claim 2,
wherein the insulating polymer is a water-soluble polymer.

11. A thermoelectric conversion layer comprising:
the conductive film according to claim 2.

12. A thermoelectric conversion layer comprising:
the conductive film according to claim 3.

13. A thermoelectric conversion layer comprising:
the conductive film according to claim 4.

14. A thermoelectric conversion layer comprising:
the conductive film according to claim 5.

15. A method for manufacturing the conductive film according to claim 2, comprising:
a step of performing a modification treatment on single-layer carbon nanotubes such that a content of oxygen atoms becomes 0.5 to 5.0 atm %;
a step of obtaining a composition which contains the single-layer carbon nanotubes, in which the content of oxygen atoms is adjusted by the modification treatment, and an insulating polymer having a polar group and in which a content of the insulating polymer with respect to a content of the single-layer carbon nanotubes is 10% to 100% by mass; and
a step of forming a conductive film on a substrate by using the composition.

16. A method for manufacturing the conductive film according to claim 3, comprising:
a step of performing a modification treatment on single-layer carbon nanotubes such that a content of oxygen atoms becomes 0.5 to 5.0 atm %;
a step of obtaining a composition which contains the single-layer carbon nanotubes, in which the content of oxygen atoms is adjusted by the modification treatment, and an insulating polymer having a polar group and in which a content of the insulating polymer with respect to a content of the single-layer carbon nanotubes is 10% to 100% by mass; and
a step of forming a conductive film on a substrate by using the composition.

17. A method for manufacturing the conductive film according to claim 4, comprising:
a step of performing a modification treatment on single-layer carbon nanotubes such that a content of oxygen atoms becomes 0.5 to 5.0 atm %;
a step of obtaining a composition which contains the single-layer carbon nanotubes, in which the content of oxygen atoms is adjusted by the modification treatment, and an insulating polymer having a polar group and in which a content of the insulating polymer with respect to a content of the single-layer carbon nanotubes is 10% to 100% by mass; and
a step of forming a conductive film on a substrate by using the composition.

18. A method for manufacturing the conductive film according to claim 5, comprising:
a step of performing a modification treatment on single-layer carbon nanotubes such that a content of oxygen atoms becomes 0.5 to 5.0 atm %;
a step of obtaining a composition which contains the single-layer carbon nanotubes, in which the content of oxygen atoms is adjusted by the modification treatment, and an insulating polymer having a polar group and in which a content of the insulating polymer with respect to a content of the single-layer carbon nanotubes is 10% to 100% by mass; and
a step of forming a conductive film on a substrate by using the composition.
